(19) United States
(12) Patent Application Publication
(10) Pub. No.: US 2020/0310563 A1
(43) Pub. Date: Oct. 1, 2020

(54) STYLUS PEN APPARATUS WITH DUAL POWER SOURCES

(71) Applicant: RENAISSER TECHNOLOGY CO., LTD., New Taipei City (TW)

(72) Inventor: Hsueh-Li CHEN, New Taipei City (TW)

(21) Appl. No.: 16/698,367

(22) Filed: Nov. 27, 2019

(30) Foreign Application Priority Data
Mar. 25, 2019 (TW) 108110352

(51) Int. Cl. G06F 3/0354; H02J 7/00; G01R 31/3835

(52) U.S. Cl. CPC G06F 3/03545; G01R 31/3835; H02J 7/0068

(57) ABSTRACT

A stylus pen apparatus with dual power sources includes a stylus pen unit and a stylus pen power supply unit. The stylus pen power supply unit includes a battery subunit, a control subunit and a charge-discharge subunit. When a power supply apparatus stops supplying power to the stylus pen power supply unit and the control subunit determines that a battery voltage of the battery subunit is greater than a battery predetermined voltage, the control subunit controls the battery subunit to supply power to the stylus pen unit. When the power supply apparatus stops supplying power to the stylus pen power supply unit and the control subunit determines that the battery voltage of the battery subunit is not greater than the battery predetermined voltage, the control subunit controls the charge-discharge subunit to supply power to the stylus pen unit.

### BACKGROUND OF THE INVENTION

### Field of the Invention

The present invention relates to a stylus pen apparatus, and especially relates to a stylus pen apparatus with dual power sources.

### Description of the Related Art

In recent years, the operations of the electronic products have great influences because of the development of the touch screens. The user no longer needs the keyboard or the mouse to input commands. The user can directly plot or write on the touch screen. In various touch screens, because the capacitance touch screen is more durable, the capacitance touch screen is widely used in the electronic products, for examples, the cellphone, the tablet computer, and so on. In order to enhance the convenience of the operation for the user, most touch screens can work with stylus pens to perform the click input or writing or plotting et cetera on the touch screen. Therefore, the stylus pen is very important. However, the disadvantage of the related art stylus pen is that after the related art stylus pen is removed from the power supply side (for example, the USB port), the related art stylus pen has only one power source (which is usually the battery) to perform the power supply for the related art stylus pen.

### SUMMARY OF THE INVENTION

In order to solve the above-mentioned problems, an object of the present invention is to provide a stylus pen apparatus with dual power sources.

In order to achieve the object of the present invention mentioned above, the stylus pen apparatus of the present invention is applied to a power supply apparatus. The stylus pen apparatus comprises a stylus pen unit and a stylus pen power supply unit. The stylus pen power supply unit is electrically connected to the power supply apparatus and the stylus pen unit. Moreover, the stylus pen power supply unit comprises a battery subunit, a control subunit and a charge-discharge subunit. The battery subunit is electrically connected to the power supply apparatus and the stylus pen unit. The control subunit is electrically connected to the power supply apparatus, the stylus pen unit and the battery subunit. The charge-discharge subunit is electrically connected to the stylus pen unit, the battery subunit and the control subunit. Moreover, when the power supply apparatus stops supplying power to the stylus pen power supply unit and the control subunit determines that a battery voltage of the battery subunit is greater than a battery predetermined voltage, the control subunit is configured to control the battery subunit to supply power to the stylus pen unit. When the power supply apparatus stops supplying power to the stylus pen power supply unit and the control subunit determines that the battery voltage of the battery subunit is not greater than the battery predetermined voltage, the control subunit is configured to control the charge-discharge subunit to supply power to the stylus pen unit.

Moreover, in the stylus pen apparatus mentioned above, the stylus pen power supply unit further comprises a battery switch subunit electrically connected to the battery subunit and the control subunit. Moreover, when the power supply apparatus stops supplying power to the stylus pen power supply unit and the control subunit determines through the battery switch subunit that the battery voltage of the battery subunit is greater than the battery predetermined voltage, the control subunit is configured to turn on the battery switch subunit, so that the battery subunit is configured to supply power to the stylus pen unit. When the power supply apparatus stops supplying power to the stylus pen power supply unit and the control subunit determines through the battery switch subunit that the battery voltage of the battery subunit is not greater than the battery predetermined voltage, the control subunit is configured to turn off the battery switch subunit, so that the charge-discharge subunit is configured to supply power to the stylus pen unit.

Moreover, in the stylus pen apparatus mentioned above, the stylus pen power supply unit further comprises a first input power detection subunit electrically connected to the power supply apparatus, the control subunit and the battery switch subunit. Moreover, when the power supply apparatus supplies power to the stylus pen power supply unit, the power supply apparatus is configured to charge the battery subunit, and the first input power detection subunit is configured to detect that the power supply apparatus supplies power to the stylus pen power supply unit, and the first input power detection subunit is configured to inform the battery switch subunit that the power supply apparatus supplies power to the stylus pen power supply unit, so that the battery switch subunit is turned on, so that the power supply apparatus is configured to charge the charge-discharge subunit through the battery switch subunit, and the power supply apparatus is configured to supply power through the battery switch subunit to the stylus pen unit and the control subunit to drive the control subunit. When the power supply apparatus supplies power to the stylus pen power supply unit and the control subunit is driven by the power supply apparatus, the control subunit is configured to clamp the battery switch subunit to be turned on.

Moreover, in the stylus pen apparatus mentioned above, the stylus pen power supply unit further comprises a battery voltage detection subunit electrically connected to the control subunit and the battery switch subunit. Moreover, the battery voltage detection subunit is configured to detect the battery voltage of the battery subunit through the battery switch subunit, and the battery voltage detection subunit is configured to inform the control subunit of the battery voltage of the battery subunit, so that the control subunit is configured to determine whether the battery voltage of the battery subunit is greater than the battery predetermined voltage or not.

Moreover, in the stylus pen apparatus mentioned above, the stylus pen power supply unit further comprises a first charging subunit electrically connected to the power supply apparatus, the battery subunit and the battery switch subunit. Moreover, when the power supply apparatus supplies power to the stylus pen power supply unit, the power supply apparatus is configured to supply power to the first charging subunit, so that the first charging subunit is configured to charge the battery subunit.

Moreover, in the stylus pen apparatus mentioned above, the stylus pen power supply unit further comprises a second charging subunit electrically connected to the charge-discharge subunit, the battery switch subunit and the battery voltage detection subunit. Moreover, when the power supply apparatus supplies power to the stylus pen power supply unit, the first charging subunit is configured to supply power to the second charging subunit through the battery switch subunit, so that the second charging subunit is configured to charge the charge-discharge subunit.

Moreover, in the stylus pen apparatus mentioned above, the stylus pen power supply unit further comprises a third charging subunit electrically connected to the stylus pen unit, the control subunit, the charge-discharge subunit and the second charging subunit. Moreover, when the power supply apparatus supplies power to the stylus pen power supply unit, the second charging subunit is configured to supply power to the third charging subunit, so that the third charging subunit is configured to supply power to the stylus pen unit and the control subunit to drive the control subunit.

Moreover, in the stylus pen apparatus mentioned above, the stylus pen power supply unit further comprises a second input power detection subunit electrically connected to the power supply apparatus, the control subunit, the first input power detection subunit and the first charging subunit. Moreover, the second input power detection subunit is configured to detect whether the power supply apparatus supplies power to the stylus pen power supply unit or not, and the second input power detection subunit is configured to inform the control subunit that whether the power supply apparatus supplies power to the stylus pen power supply unit or not.

Moreover, in the stylus pen apparatus mentioned above, the stylus pen power supply unit further comprises an auxiliary voltage detection subunit and a voltage control subunit. The auxiliary voltage detection subunit is electrically connected to the control subunit, the charge-discharge subunit, the second charging subunit and the third charging subunit. The voltage control subunit is electrically connected to the control subunit and the third charging subunit. Moreover, the auxiliary voltage detection subunit is configured to detect a voltage of the charge-discharge subunit and inform the control subunit of the voltage of the charge-discharge subunit. Moreover, when the power supply apparatus stops supplying power to the stylus pen power supply unit and the control subunit determines that the battery voltage of the battery subunit is not greater than the battery predetermined voltage and the auxiliary voltage detection subunit detects that the voltage of the charge-discharge subunit is greater than a predetermined voltage, the control subunit is configured to control the third charging subunit by the voltage control subunit to supply a first output voltage to the stylus pen unit. When the power supply apparatus stops supplying power to the stylus pen power supply unit and the control subunit determines that the battery voltage of the battery subunit is not greater than the battery predetermined voltage and the auxiliary voltage detection subunit detects that the voltage of the charge-discharge subunit is not greater than the predetermined voltage, the control subunit is configured to control the third charging subunit by the voltage control subunit to supply a second output voltage to the stylus pen unit. The first output voltage is greater than the second output voltage.

Moreover, in the stylus pen apparatus mentioned above, the battery subunit is a lithium ion battery. The charge-discharge subunit is a super capacitor. The first charging subunit is a step-down charging integrated circuit. The second charging subunit is a step-down charging integrated circuit. The third charging subunit is a step-up charging integrated circuit.

The advantage of the present invention is to provide the stylus pen with two power sources.

Please refer to the detailed descriptions and figures of the present invention mentioned below for further understanding the technology, method and effect of the present invention achieving the predetermined purposes. It believes that the purposes, characteristic and features of the present invention can be understood deeply and specifically. However, the figures are only for references and descriptions, but the present invention is not limited by the figures.

### BRIEF DESCRIPTION OF DRAWING

FIG. 1 shows a block diagram of the stylus pen apparatus of the present invention.

FIG. 2 shows an arrangement diagram of the stylus pen apparatus of the present invention.

FIG. 3 shows a circuit diagram of the first input power detection subunit of the present invention.

FIG. 4 shows a circuit block diagram of the embodiment of FIG. 1 of the present invention.

### DETAILED DESCRIPTION OF THE INVENTION

In the present disclosure, numerous specific details are provided, to provide a thorough understanding of embodiments of the invention. Persons of ordinary skill in the art will recognize, however, that the present invention can be practiced without one or more of the specific details. In other instances, well-known details are not shown or described to avoid obscuring aspects of the present invention. Now please refer to the figures for the explanation of the technical content and the detailed description of the present invention:

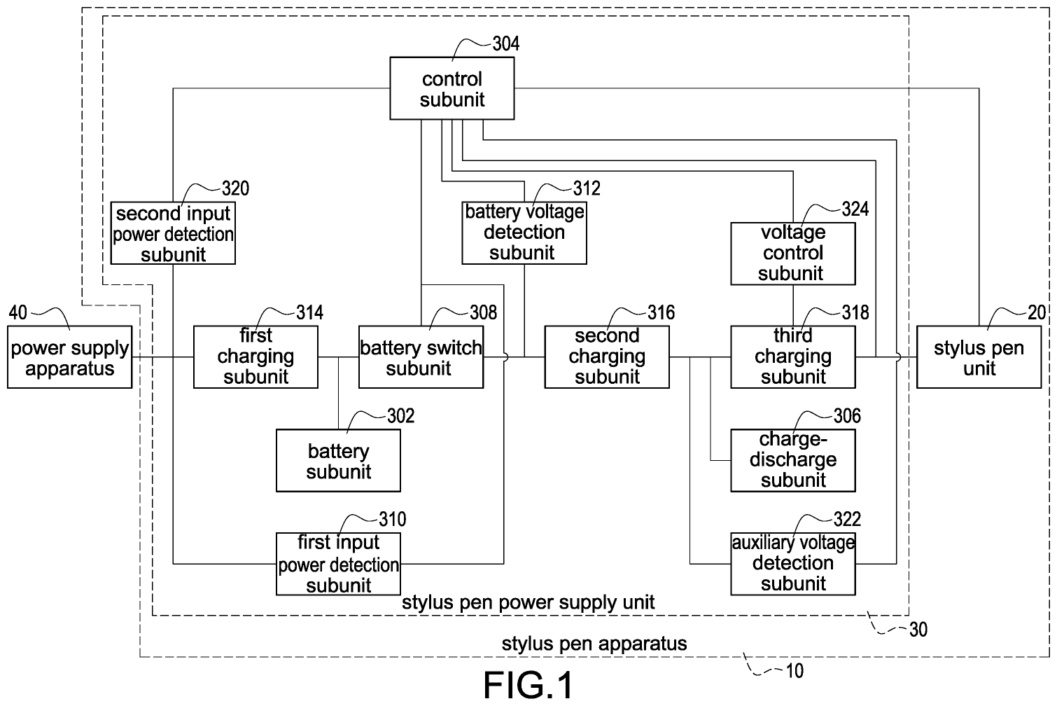

FIG. 1 shows a block diagram of the stylus pen apparatus of the present invention. A stylus pen apparatus 10 with dual power sources is applied to a power supply apparatus 40. The stylus pen apparatus 10 comprises a stylus pen unit 20 and a stylus pen power supply unit 30. The stylus pen power supply unit 30 comprises a battery subunit 302, a control subunit 304, a charge-discharge subunit 306, a battery switch subunit 308, a first input power detection subunit 310, a battery voltage detection subunit 312, a first charging subunit 314, a second charging subunit 316, a third charging subunit 318, a second input power detection subunit 320, an auxiliary voltage detection subunit 322 and a voltage control subunit 324. The components mentioned above are electrically connected to each other. Just with the stylus pen unit 20, the battery subunit 302, the control subunit 304 and the charge-discharge subunit 306, the present invention can achieve the effect of the present invention.

The stylus pen apparatus 10 is used to plot, write or input commands et cetera on a touch screen (not shown in FIG. 1). The power supply apparatus 40 is, for example, a USB power generation circuit supplying 5 volts voltage. The stylus pen power supply unit 30 supplies power to drive the stylus pen unit 20. The stylus pen unit 20 is a stylus pen except the power part; the power part is the stylus pen power supply unit 30. The battery subunit 302 is, for example but not limited to, a lithium ion battery. The control subunit 304 is, for example but not limited to, a microcontroller. The charge-discharge subunit 306 is, for example but not limited to, a super capacitor. The battery switch subunit 308 is, for example but not limited to, a switch integrated circuit.

When the power supply apparatus 40 supplies power to the stylus pen power supply unit 30 (for example, when the stylus pen apparatus 10 is connected to a USB port): the power supply apparatus 40 supplies power to the first charging subunit 314, so that the first charging subunit 314 is configured to charge the battery subunit 302, and the first input power detection subunit 310 is configured to detect that the power supply apparatus 40 supplies power to the stylus pen power supply unit 30, and the first input power detection subunit 310 is configured to inform the battery switch subunit 308 that the power supply apparatus 40 supplies power to the stylus pen power supply unit 30, so that the battery switch subunit 308 is turned on, so that the first charging subunit 314 is configured to supply power to the second charging subunit 316 through the battery switch subunit 308, so that the second charging subunit 316 is configured to charge the charge-discharge subunit 306 and supply power to the third charging subunit 318, so that the third charging subunit 318 is configured to supply power to the stylus pen unit 20 and the control subunit 304 to drive the stylus pen unit 20 and the control subunit 304. Then, the control subunit 304 is configured to clamp the battery switch subunit 308 as being turned on, so that the power supply apparatus 40 can stably and continuously charge and supply power to the components in the stylus pen apparatus 10 mentioned above.

When the power supply apparatus 40 stops supplying power to the stylus pen power supply unit 30 (for example, when the stylus pen apparatus 10 is removed from the USB port): the second input power detection subunit 320 is configured to detect that the power supply apparatus 40 stops supplying power to the stylus pen power supply unit 30, and the second input power detection subunit 320 is configured to inform the control subunit 304 that the power supply apparatus 40 stops supplying power to the stylus pen power supply unit 30, so that the control subunit 304 is configured to no longer clamp the battery switch subunit 308 as being turned on. At this time, following contents determine whether the battery switch subunit 308 is turned on or turned off.

Firstly, the battery switch subunit 308 is turned on, so that the battery voltage detection subunit 312 detects a battery voltage of the battery subunit 302 through the battery switch subunit 308 and informs the control subunit 304 of the battery voltage of the battery subunit 302, so that the control subunit 304 determines whether the battery voltage of the battery subunit 302 is greater than a battery predetermined voltage (for example, 3.6 volts) or not.

If the control subunit 304 determines that the battery voltage of the battery subunit 302 is greater than the battery predetermined voltage, the control subunit 304 turns on the battery switch subunit 308, so that the battery subunit 302 supplies power to the second charging subunit 316, so that the second charging subunit 316 charges the charge-discharge subunit 306 and supplies power to the third charging subunit 318, so that the third charging subunit 318 supplies power to the stylus pen unit 20 and the control subunit 304 to drive the stylus pen unit 20 and the control subunit 304.

If the control subunit 304 determines that the battery voltage of the battery subunit 302 is not greater than the battery predetermined voltage, the control subunit 304 turns off the battery switch subunit 308, so that the charge-discharge subunit 306 discharges/supplies power to the third charging subunit 318, wherein a voltage of the charge-discharge subunit 306 will be discharged from, for example, 2.7 volts to 0 volt. Then, the third charging subunit 318 supplies power to the stylus pen unit 20 and the control subunit 304 to drive the stylus pen unit 20 and the control subunit 304.

The auxiliary voltage detection subunit 322 is configured to detect the voltage of the charge-discharge subunit 306 and inform the control subunit 304 of the voltage of the charge-discharge subunit 306. When the power supply apparatus 40 stops supplying power to the stylus pen power supply unit 30 and the control subunit 304 determines that the battery voltage of the battery subunit 302 is not greater than the battery predetermined voltage and the auxiliary voltage detection subunit 322 detects that the voltage of the charge-discharge subunit 306 is greater than a predetermined voltage (for example, 1.4 volts), the control subunit 304 is configured to control the third charging subunit 318 by the voltage control subunit 324 to supply a first output voltage (for example, 2.8 volts) to the stylus pen unit 20 and the control subunit 304. When the power supply apparatus 40 stops supplying power to the stylus pen power supply unit 30 and the control subunit 304 determines that the battery voltage of the battery subunit 302 is not greater than the battery predetermined voltage and the auxiliary voltage detection subunit 322 detects that the voltage of the charge-discharge subunit 306 is not greater than the predetermined voltage, the control subunit 304 is configured to control the third charging subunit 318 by the voltage control subunit 324 to supply a second output voltage (for example, 2.2 volts) to the stylus pen unit 20 and the control subunit 304. The first output voltage is greater than the second output voltage. Therefore, a power-supplying time of the charge-discharge subunit 306 can be extended.

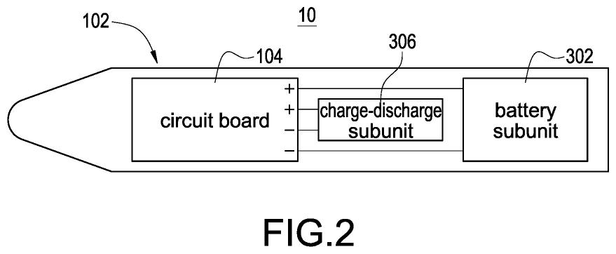

The first charging subunit 314 is a step-down charging integrated circuit; for example, a received 5 volts voltage is decreased as 4.2 volts voltage to output. The second charging subunit 316 is a step-down charging integrated circuit; for example, a received 4.2 volts voltage is decreased as 2.7 volts voltage to output. The third charging subunit 318 is a step-up charging integrated circuit; for example, a received 2.7˜1.5 volts voltage is increased as 2.8 volts voltage to output, or a received voltage less than 1.5 volts is increased as 2.2 volts voltage to output. If the battery voltage of the battery subunit 302 is not greater than the battery predetermined voltage but the battery subunit 302 still supplies power, the battery subunit 302 will be damaged easily, so that the present invention sets that if the battery voltage of the battery subunit 302 is not greater than the battery predetermined voltage, the battery subunit 302 stops supplying power. FIG. 2 shows an arrangement diagram of the stylus pen apparatus of the present invention. The stylus pen apparatus 10 further comprises a stylus pen housing 102 and a circuit board 104. The stylus pen housing 102 covers the electronic components mentioned above. The electronic components mentioned above are welded on and connected to the circuit board 104. Both the battery subunit 302 and the charge-discharge subunit 306 are built in the stylus pen housing 102 of the stylus pen apparatus 10.

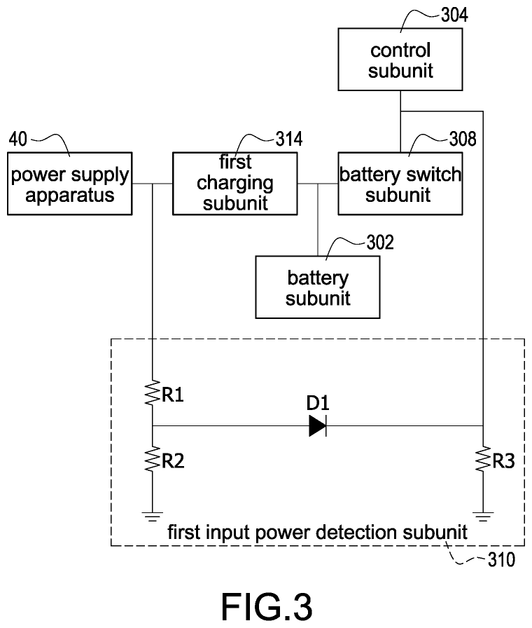

FIG. 3 shows a circuit diagram of the first input power detection subunit of the present invention. The first input power detection subunit 310 comprises a first resistor R1, a second resistor R2, a diode D1 and a third resistor R3. One side of the first resistor R1 is connected to the power supply apparatus 40. One side of the second resistor R2 is connected to the other side of the first resistor R1. The other side of the second resistor R2 is connected to ground. An anode of the diode D1 is connected to the other side of the first resistor R1 and one side of the second resistor R2. A cathode of the diode D1 is connected to the control subunit 304 and the battery switch subunit 308. One side of the third resistor R3 is connected to the control subunit 304, the battery switch subunit 308 and the cathode of the diode D1. The other side of the third resistor R3 is connected to ground.

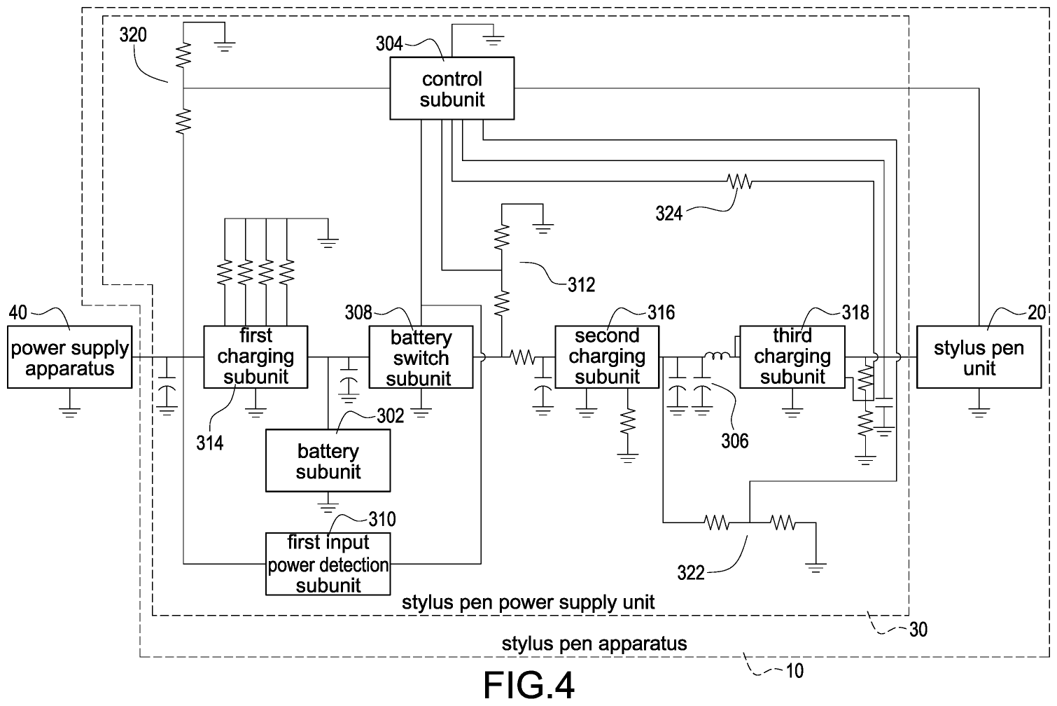

FIG. 4 shows a circuit block diagram of the embodiment of FIG. 1 of the present invention. As shown in FIG. 4, the battery voltage detection subunit 312, the second input power detection subunit 320 and the auxiliary voltage detection subunit 322 are voltage division resistor circuits to obtain detected voltages to inform objects. The circuit of the first input power detection subunit 310 is shown in FIG. 3.

In conclusion, the advantage of the present invention is to provide the stylus pen with two power sources, for examples, the lithium ion battery and the super capacitor. When the stylus pen apparatus 10 of the present invention is charged, both the battery subunit 302 and the charge-discharge subunit 306 are charged simultaneously. The present invention utilizes the super capacitor to discharge/charge rapidly, and utilizes the lithium ion battery to supply long-time usage power. The present invention comprises at least two advantages as following:

1. If the stylus pen apparatus 10 is charged for 15 seconds, the stylus pen apparatus 10 can be used continuously over 30 minutes.

2. Even the temperature is very high or very low, if the stylus pen apparatus 10 is charged for 15 seconds, the stylus pen apparatus 10 can still be used continuously over 30 minutes. Namely, the stylus pen apparatus 10 of the present invention is not affected by the temperature.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A stylus pen apparatus with dual power sources applied to a power supply apparatus, the stylus pen apparatus comprising:
a stylus pen unit; and
a stylus pen power supply unit electrically connected to the power supply apparatus and the stylus pen unit,
wherein the stylus pen power supply unit comprises:
a battery subunit electrically connected to the power supply apparatus and the stylus pen unit;
a control subunit electrically connected to the power supply apparatus, the stylus pen unit and the battery subunit; and
a charge-discharge subunit electrically connected to the stylus pen unit, the battery subunit and the control subunit,
wherein when the power supply apparatus stops supplying power to the stylus pen power supply unit and the control subunit determines that a battery voltage of the battery subunit is greater than a battery predetermined voltage, the control subunit is configured to control the battery subunit to supply power to the stylus pen unit; when the power supply apparatus stops supplying power to the stylus pen power supply unit and the control subunit determines that the battery voltage of the battery subunit is not greater than the battery predetermined voltage, the control subunit is configured to control the charge-discharge subunit to supply power to the stylus pen unit.

2. The stylus pen apparatus in claim 1, wherein the stylus pen power supply unit further comprises:
a battery switch subunit electrically connected to the battery subunit and the control subunit.

3. The stylus pen apparatus in claim 2, wherein the stylus pen power supply unit further comprises:
a first input power detection subunit electrically connected to the power supply apparatus, the control subunit and the battery switch subunit.

4. The stylus pen apparatus in claim 3, wherein the stylus pen power supply unit further comprises:
a battery voltage detection subunit electrically connected to the control subunit and the battery switch subunit,
wherein the battery voltage detection subunit is configured to detect the battery voltage of the battery subunit through the battery switch subunit, and the battery voltage detection subunit is configured to inform the control subunit of the battery voltage of the battery subunit, so that the control subunit is configured to determine whether the battery voltage of the battery subunit is greater than the battery predetermined voltage or not.

5. The stylus pen apparatus in claim 4, wherein the stylus pen power supply unit further comprises:
a first charging subunit electrically connected to the power supply apparatus, the battery subunit and the battery switch subunit,
wherein when the power supply apparatus supplies power to the stylus pen power supply unit, the power supply apparatus is configured to supply power to the first charging subunit, so that the first charging subunit is configured to charge the battery subunit.

6. The stylus pen apparatus in claim 5, wherein the stylus pen power supply unit further comprises:
a second charging subunit electrically connected to the charge-discharge subunit, the battery switch subunit and the battery voltage detection subunit,
wherein when the power supply apparatus supplies power to the stylus pen power supply unit, the first charging subunit is configured to supply power to the second charging subunit through the battery switch subunit, so that the second charging subunit is configured to charge the charge-discharge subunit.

7. The stylus pen apparatus in claim 6, wherein the stylus pen power supply unit further comprises:
a third charging subunit electrically connected to the stylus pen unit, the control subunit, the charge-discharge subunit and the second charging subunit,
wherein when the power supply apparatus supplies power to the stylus pen power supply unit, the second charging subunit is configured to supply power to the third charging subunit, so that the third charging subunit is configured to supply power to the stylus pen unit and the control subunit to drive the control subunit.

8. The stylus pen apparatus in claim 7, wherein the stylus pen power supply unit further comprises:
a second input power detection subunit electrically connected to the power supply apparatus, the control subunit, the first input power detection subunit and the first charging subunit,
wherein the second input power detection subunit is configured to detect whether the power supply apparatus supplies power to the stylus pen power supply unit or not, and the second input power detection subunit is configured to inform the control subunit that whether the power supply apparatus supplies power to the stylus pen power supply unit or not.

9. The stylus pen apparatus in claim 8, wherein the stylus pen power supply unit further comprises:
an auxiliary voltage detection subunit electrically connected to the control subunit, the charge-discharge subunit, the second charging subunit and the third charging subunit,
wherein the auxiliary voltage detection subunit is configured to detect a voltage of the charge-discharge subunit and inform the control subunit of the voltage of the charge-discharge subunit.

10. The stylus pen apparatus in claim 9, wherein the battery subunit is a lithium ion battery; the charge-discharge subunit is a super capacitor; the first charging subunit is a step-down charging integrated circuit; the second charging subunit is a step-down charging integrated circuit; the third charging subunit is a step-up charging integrated circuit.
